(19) United States
(12) Patent Application Publication
(10) Pub. No.: US 2026/0356588 A1
(43) Pub. Date: Nov. 12, 2026

(54) Automated Warehouse

(71) Applicant: Daifuku Co., Ltd., Osaka-shi (JP)

(72) Inventor: Masayuki Ikeya, Komaki-shi (JP)

(21) Appl. No.: 19/670,071

(22) Filed: May 7, 2026

(30) Foreign Application Priority Data
May 8, 2025 (JP) 2025-077913

(51) Int. Cl. B65G 1/137; H10P 72/30

(52) U.S. Cl. CPC B65G 1/1371; H10P 72/3218; B65G 2201/0297; B65G 2203/0216

(57) ABSTRACT

A control system causes an identification information obtainer disposed in an incoming section to obtain identification information of an incoming article, causes a transporter to transport the incoming article to a storage destination compartment, generates article management information including information indicating a position of the storage destination compartment in a manner associated with the identification information, and performs regeneration of the article management information in response to an event that causes the regeneration to be performed. The regeneration includes causing the transporter to transport a target article to the incoming section, causing the identification information obtainer to obtain the identification information of the target article, causing the transporter to transport the target article to a restorage destination compartment, and regenerating the article management information including information indicating a position of the restorage destination compartment in a manner associated with the identification information.

### CROSS-REFERENCE TO RELATED APPLICATION

This application claims priority to Japanese Patent Application No. 2025-077913 filed May. 8, 2025, the disclosure of which is hereby incorporated by reference in its entirety.

### BACKGROUND OF THE INVENTION

### FIELD OF THE INVENTION

The present invention relates to an automated warehouse including a storage rack with multiple compartments that can each store an article, an incoming section in which articles are received into the automated warehouse, a transporter that transports articles between the incoming section and any of the compartments, and a control system.

### DESCRIPTION OF RELATED ART

An example of such an automated warehouse is described in Japanese Unexamined Patent Application Publication No. 5-208716. In the background described hereafter, reference signs in parentheses are the reference signs in Japanese Unexamined Patent Application Publication No. 5-208716.

A control system (5) in the automated warehouse described in Japanese Unexamined Patent Application Publication No. 5-208716 generates and stores article management information when articles (2) are received into the automated warehouse. The article management information includes the identification information of each article (2) in a manner associated with storage position information indicating the position of a compartment (8) in which the article (2) is to be stored.

In the automated warehouse described above, when the control system (5) is, for example, restarted due to a breakdown or a power failure, the article management information may be regenerated to maintain the accuracy of the article management information for some or all of the articles (2) on a storage rack (4).

In the automated warehouse described above, a barcode (3) is attached to a side surface of each article (2) to indicate the identification information of the article (2), and a barcode reader (6) is installed on a transporter (1) as an identification information obtainer that obtains the identification information. When the article management information is to be regenerated, the barcode (3) attached to the side surface of the article (2) stored in a compartment (8) is read by the barcode reader (6). This facilitates regeneration of the article management information.

To determine the type of article (2), for example, the shape of the article (2) may further be obtained as identification information. In this case, a sensor or another device for detecting the shape of the article (2) is to be installed separately as an identification information obtainer. However, installing such an identification information obtainer on the transporter (1) may be difficult. The identification information obtainer may thus be installed in any of the compartments (8) instead of being installed on the transporter (1). When the article management information is to be regenerated, the article (2) is stored into the compartment (8) to allow detection of the shape of the article (2) with the identification information obtainer.

However, the compartment (8) including the identification information obtainer is used only when the article management information is to be regenerated. This structure can decrease the number of articles (2) storable in the storage rack (4).

### SUMMARY OF THE INVENTION

Automated warehouses that are thus awaited can avoid decreasing the number of articles storable in storage racks due to installation of an identification information obtainer.

In response to this, an automated warehouse includes a storage rack including a plurality of compartments that each store an article, at least one incoming section in which articles are received into the automated warehouse, a transporter that transports articles between the at least one incoming section and a compartment among the plurality of compartments, a control system, and at least one identification information obtainer disposed in the at least one incoming section to obtain identification information of articles. The control system performs a first information obtaining process to cause the at least one identification information obtainer to obtain the identification information of an incoming article that is an article moved to the at least one incoming section to be received into the automated warehouse, and a first incoming process to cause the transporter to transport the incoming article to a storage destination compartment after the first information obtaining process. The storage destination compartment is a compartment among the plurality of compartments. The control system performs a first generation process to generate article management information including information indicating a position of the storage destination compartment in a manner associated with the identification information obtained in the first information obtaining process, and a regeneration process to perform regeneration of the article management information in response to an event that causes the regeneration to be performed. The regeneration process includes a first transport process for causing the transporter to transport at least one target article to the at least one incoming section from a compartment among the plurality of compartments. The at least one target article is at least one article corresponding to the article management information to be regenerated. The regeneration process includes a second information obtaining process for causing the at least one identification information obtainer to obtain the identification information of the at least one target article after the first transport process, and a second transport process for causing the transporter to transport the at least one target article to a restorage destination compartment after the second information obtaining process. The restorage destination compartment is a compartment among the plurality of compartments. The regeneration process includes a second generation process for regenerating the article management information including information indicating a position of the restorage destination compartment in a manner associated with the identification information obtained in the second information obtaining process.

In this structure, the identification information obtainer disposed in the incoming section obtains both the identification information of the incoming article in the first information obtaining process and the identification information of the target article in the second information obtaining process. This allows the identification obtaining device installed in the incoming section to be shared by both the first information obtaining process and the second information obtaining process without an identification obtaining device being separately installed in any of the compartments in addition to the incoming section. This can avoid decreasing the number of articles storable in the storage rack due to installation of the identification information obtainer.

The above structure also reduces the number of identification information obtainers being installed, as compared with the structure in which the identification information obtainer is installed separately in any of the compartments in addition to the incoming section.

### BRIEF DESCRIPTION OF THE DRAWINGS

FIG. 1 is a diagram of an automated warehouse according to an embodiment.

FIG. 2 is a control block diagram of the automated warehouse according to the embodiment.

FIG. 3 is a diagram of an example of a first information obtaining process.

FIG. 4 is a diagram of an example of a first incoming process.

FIG. 5 is a diagram of an example of a first transport process.

FIG. 6 is a diagram of an example of a second information obtaining process.

FIG. 7 is a diagram of an example of a second transport process.

FIG. 8 is a diagram of an example of control performed when a target article is determined to be transported out of the automated warehouse before a regeneration process for all target articles is complete.

FIG. 9 is a diagram of an example of control for performing a regeneration process for each of multiple target articles.

FIG. 10 is a diagram of an example of control for performing a regeneration process for each of multiple target articles.

### DESCRIPTION OF THE INVENTION

An automated warehouse 100 according to one or more embodiments will be described below with reference to the drawings.

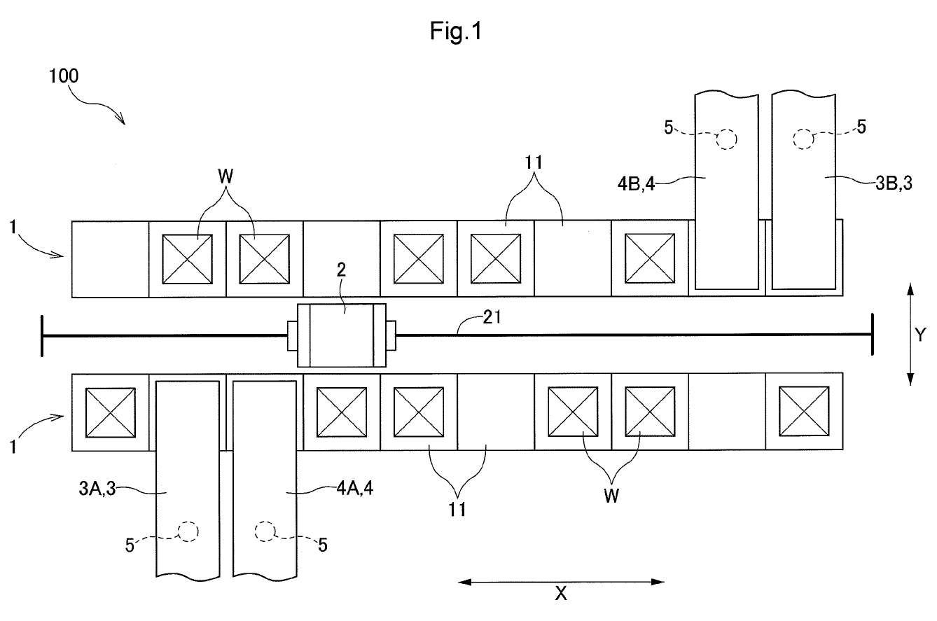

As shown in FIG. 1, the automated warehouse 100 includes a storage rack 1, a transporter 2, and an incoming section 3. In the present embodiment, the automated warehouse 100 further includes an outgoing section 4.

The storage rack 1 includes multiple compartments 11. Each compartment 11 can store an article W. In the present embodiment, the article W is a front-opening unified pod (FOUP) or a front-opening shipping box (FOSB) storing a semiconductor substrate. The article W has an identifier holder (e.g., a two-dimensional code or a radio frequency identification or RFID tag) holding an identifier for identifying the article W.

In the present embodiment, the compartments 11 are arranged in a first direction X along a horizontal plane. Although not shown, the compartments 11 are also arranged vertically. In the present embodiment, a pair of storage racks 1 are disposed in a manner spaced from each other in a second direction Y. The second direction Y is orthogonal to the first direction X as viewed vertically.

The transporter 2 transports articles W between the incoming section 3 and any of the compartments 11. In the present embodiment, the transporter 2 also transports articles W between the outgoing section 4 and any of the compartments 11. In the present embodiment, the transporter 2 is a stack crane that travels along a rail 21. The rail 21 extends in the first direction X. The rail 21 is disposed between the pair of storage racks 1 in the second direction Y.

The incoming section 3 is a section in which articles W are received into the automated warehouse 100. In the present embodiment, the incoming section 3 is a conveyor that transports articles W in the second direction Y. The incoming section 3 is disposed in the storage rack 1 in place of one of the compartments 11. Typically, the incoming section 3 transports articles W toward the rail 21, but may transport articles W away from the rail 21.

In the present embodiment, the automated warehouse 100 includes multiple incoming sections 3. The multiple incoming sections 3 include a first incoming section 3A and a second incoming section 3B. In the illustrated example, the first incoming section 3A is on one of the storage racks 1, and the second incoming section 3B is on the other. The two incoming sections 3 are separate in the second direction Y across the rail 21 and spaced from each other in the first direction X.

The outgoing section 4 is a section from which articles W are transported out of the automated warehouse 100. In the present embodiment, the outgoing section 4 is a conveyor that transports articles W in the second direction Y. The outgoing section 4 is disposed in the storage rack 1 in place of one of the compartments 11. Typically, the outgoing section 4 transports articles W away from the rail 21, but may transport articles W toward the rail 21.

In the present embodiment, the automated warehouse 100 includes multiple outgoing sections 4. The multiple outgoing sections 4 include a first outgoing section 4A and a second outgoing section 4B. In the illustrated example, the first outgoing section 4A is adjacent to the first incoming section 3A, and the second outgoing section 4B is adjacent to the second incoming section 3B. The two outgoing sections 4 are separate in the second direction Y across the rail 21 and spaced from each other in the first direction X.

As shown in FIG. 1, the automated warehouse 100 includes identification information obtainers 5. The identification information obtainers 5 obtain identification information of articles W. In the present embodiment, each identification information obtainer 5 includes a reader that reads the identifier held by the identifier holder attached to each article W and a shape detector that detects the shape of each article W. In the present embodiment, the identification information of articles W includes an identifier held by the identifier holder attached to each article W and the type of article W determined based on the shape of the article W.

The identification information obtainers 5 are disposed at the incoming sections 3. In the present embodiment, the identification information obtainers 5 are disposed at the respective incoming sections 3. The identification information obtainers 5 are also disposed at the respective outgoing sections 4.

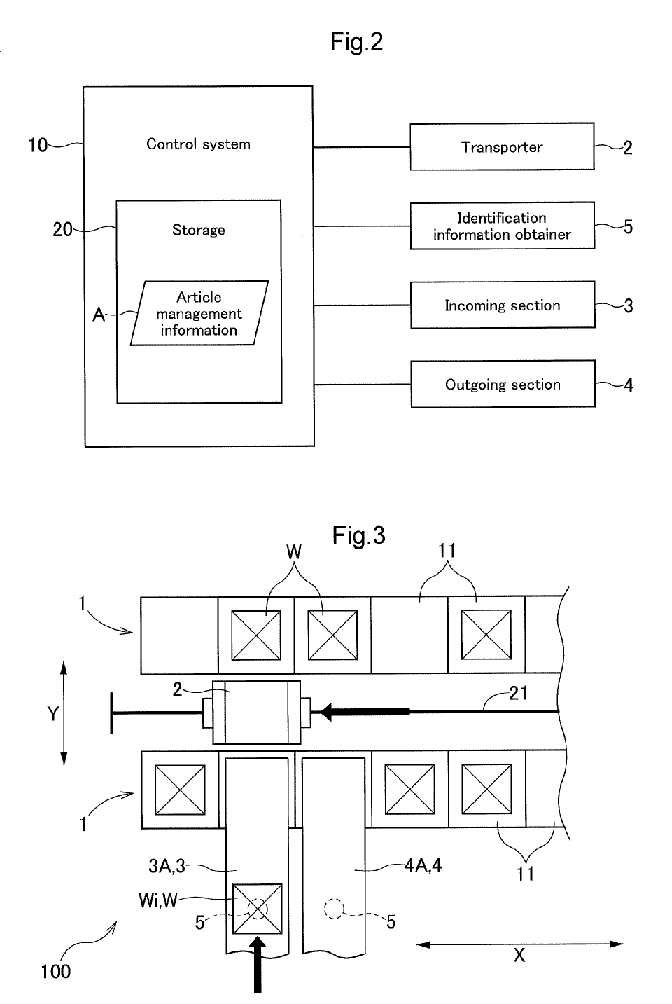

As shown in FIG. 2, the automated warehouse 100 includes a control system 10. The control system 10 controls the transporter 2, the incoming sections 3, and the identification information obtainers 5. In the present embodiment, the control system 10 further controls the outgoing sections 4. In the present embodiment, the control system 10 includes a storage 20 that stores various items of information.

The control system 10 performs a first information obtaining process, a first incoming process, a first generation process, and a regeneration process.

As shown in FIG. 3, the first information obtaining process causes one of the identification information obtainers 5 to obtain identification information of an incoming article Wi. The incoming article Wi is an article W moved to one of the incoming sections 3 to be received into the automated warehouse 100. In the example shown in FIG. 3, the control system 10 causes the incoming section 3 to transport the incoming article Wi to a position at which the identification information can be obtained by the identification information obtainer 5. The control system 10 then causes the identification information obtainer 5 to obtain the identification information of the incoming article Wi.

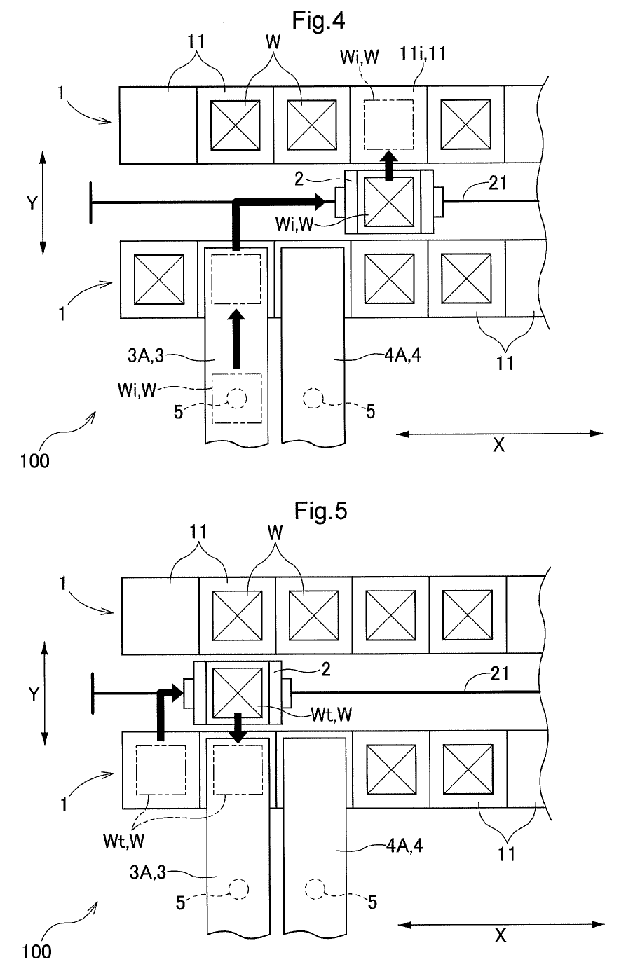

As shown in FIG. 4, the first incoming process causes the transporter 2 to transport the incoming article Wi to a storage destination compartment 11i after the first information obtaining process. The storage destination compartment 11i is one of the compartments 11. In the example shown in FIG. 4, the control system 10 causes the incoming section 3 to transport the incoming article Wi to a position at which the incoming article Wi can be received by the transporter 2. The control system 10 then causes the transporter 2 to receive the incoming article Wi from the incoming section 3 and transport the article Wi to the storage destination compartment 11i.

The first generation process generates article management information A that includes information indicating the position of the storage destination compartment 11i in a manner associated with the identification information obtained in the first information obtaining process. In the present embodiment, the control system 10 generates the article management information A and stores the article management information A into the storage 20. The first generation process may be performed in parallel with or after the first incoming process.

The regeneration process regenerates the article management information A when the article management information A is to be regenerated. In this example, the article management information A is to be regenerated when, for example, the control system 10 is restarted due to a breakdown or a power failure.

The regeneration process includes a first transport process, a second information obtaining process, a second transport process, and a second generation process.

As shown in FIG. 5, the first transport process causes the transporter 2 to transport a target article Wt from one of the compartments 11 to one of the incoming sections 3. The target article Wt is an article W corresponding to the article management information A to be regenerated. In the example shown in FIG. 5, the control system 10 causes the transporter 2 to receive the target article Wt from the compartment 11 and transfer the target article Wt to the incoming section 3.

As shown in FIG. 6, the second information obtaining process causes one of the identification information obtainers 5 to obtain the identification information of the target article Wt after the first transport process. In the example shown in FIG. 6, the control system 10 causes the incoming section 3 to transport the target article Wt to a position at which the identification information can be obtained by the identification information obtainer 5. In this state, the incoming section 3 transports the target article Wt in a direction opposite to the typical transport direction for, for example, the first information obtaining process. The control system 10 then causes the identification information obtainer 5 to obtain the identification information of the target article Wt.

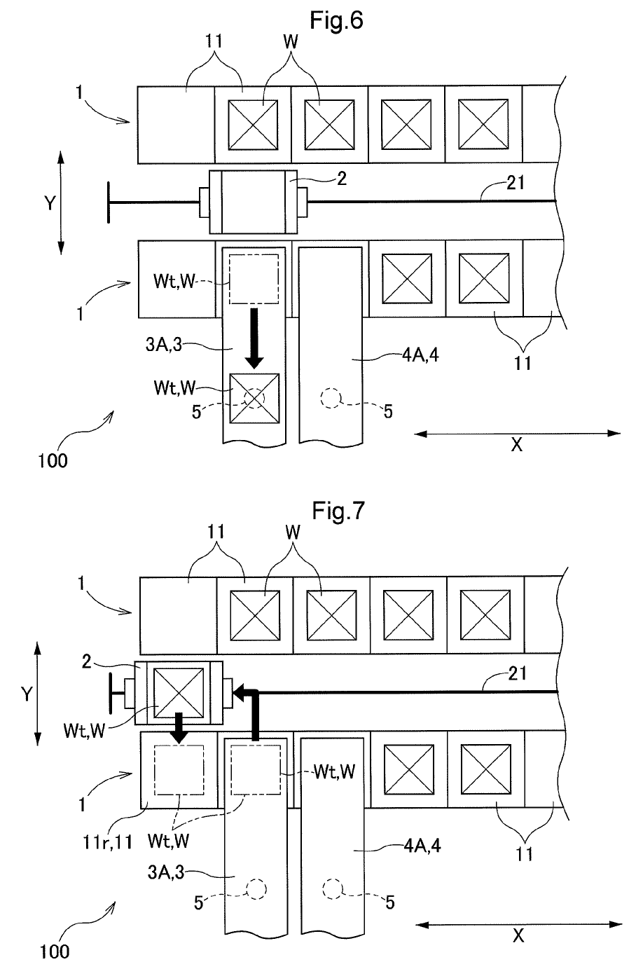

As shown in FIG. 7, the second transport process causes the transporter 2 to transport the target article Wt to a restorage destination compartment 11r after the second information obtaining process. The restorage destination compartment 11r is one of the multiple compartments 11. The control system 10 sets a compartment 11 storing no article W as the restorage destination compartment 11r. In the example shown in FIG. 7, the control system 10 sets the compartment 11 that has originally stored the target article Wt (the compartment 11 as a transport source of the target article Wt in the first transport process) as the restorage destination compartment 11r, and causes the transporter 2 to transport the target article Wt to the restorage destination compartment 11r. The control system may set a compartment 11 other than the compartment 11 that has originally stored the target article Wt as the restorage destination compartment 11r.

The second generation process regenerates the article management information A including the information indicating the position of the restorage destination compartment 11r in a manner associated with the identification information obtained in the second information obtaining process. In the present embodiment, the control system 10 regenerates the article management information A and stores the resulting article management information A into the storage 20. The second generation process may be performed in parallel with or after the second transport process.

When the automated warehouse 100 has multiple target articles Wt, the regeneration process may be performed for all or some of the target articles Wt.

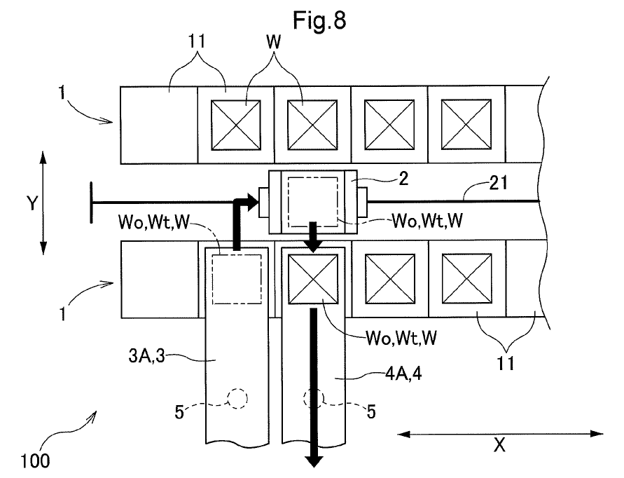

In the present embodiment, the regeneration process is performed for each of the target articles Wt. When one of the target articles Wt, which is referred to as an outgoing article Wo, is determined to be transported out of the automated warehouse 100 before the regeneration process is complete for all the target articles Wt as shown in FIG. 8 and when the identification information of the outgoing article Wo is obtained through the second information obtaining process, the control system 10 causes the transporter 2 to transport the outgoing article Wo to one of the outgoing sections 4 with higher priority over performing the regeneration process for the target articles Wt other than the outgoing article Wo. In this example, the outgoing article Wo is determined to be transported out of the automated warehouse 100 when, for example, the control system 10 receives a transport-out command from a host controller.

In the example shown in FIG. 8, the regeneration process is not complete for the outgoing article Wo at the time when the outgoing article Wo is determined to be transported out of the automated warehouse 100. Thus, the control system 10 causes the transporter 2 to transport the outgoing article Wo from the incoming section 3 to the outgoing section 4 without performing the second transport process for the outgoing article Wo after the second information obtaining process. In another example, the regeneration process is complete for the outgoing article Wo at the time when the outgoing article Wo is determined to be transported out of the automated warehouse 100 and stored in one of the compartments 11. In this case, the control system 10 causes the transporter 2 to transport the outgoing article Wo from the compartment 11 to the outgoing section 4. When an article W is determined to be received into the automated warehouse 100 before the regeneration process is complete for all the target articles Wt, the control system 10 does not receive the article W until the regeneration process is complete for all the target articles Wt.

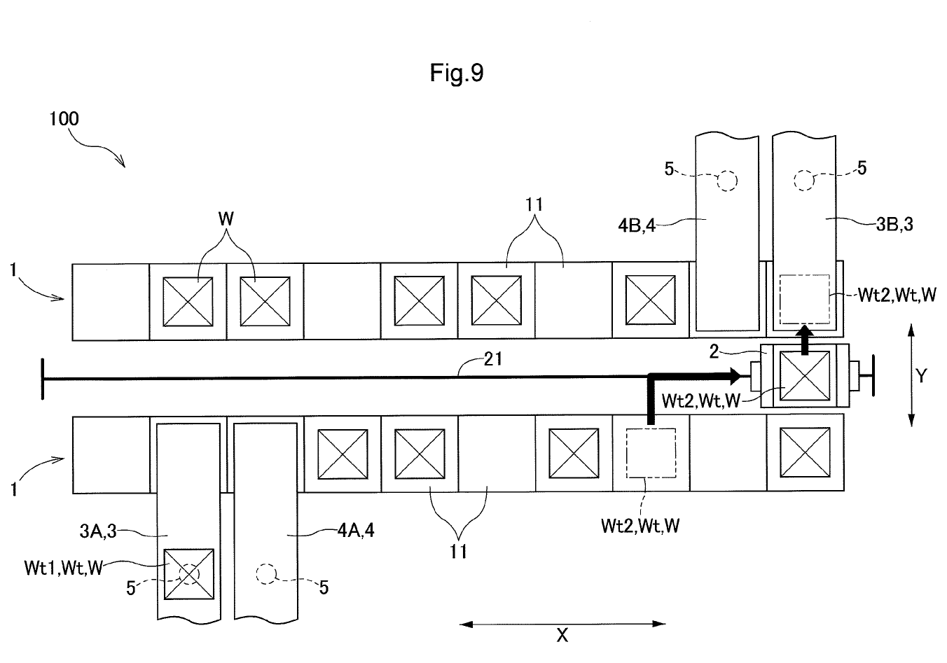

In the present embodiment, when performing the regeneration process for each of the target articles Wt, the control system 10 performs the first transport process for each of the target articles Wt to cause the transporter 2 to distribute the multiple target articles Wt to multiple incoming sections 3, as shown in FIG. 9. The control system 10 then performs the second information obtaining process for each target article Wt to cause the multiple identification information obtainers 5 to obtain the identification information of the multiple target article Wt.

In the present embodiment, when performing the regeneration process for each target article Wt, the control system 10 causes the identification information obtainer 5 disposed in the first incoming section 3A to obtain, in the second information obtaining process, the identification information of a first target article Wt1 in a first period, and causes the transporter 2 to transport, in the first transport process, a second target article Wt2 to the second incoming section 3B in a second period overlapping the first period. The first target article Wt1 is one of the target articles Wt. The second target article Wt2 is another target article Wt different from the first target article Wt1. After the second target article Wt2 is transported to the second incoming section 3B by the transporter 2 in the first transport process, the second transport process may be performed for the first target article Wt1 in a period overlapping the period in which the identification information obtainer 5 disposed in the second incoming section 3B obtains the identification information of the second target article Wt2 in the second information obtaining process. The overlap of the two periods includes a partial overlap between one period and the other, as well as the inclusion of one period in the other period.

In the present embodiment, the control system 10 selects the destination incoming section 3 in the first transport process to equalize the load of the multiple identification information obtainers 5 in the second information obtaining process. In the first transport process, the control system 10 causes the transporter 2 to transport the target article Wt to the incoming section 3, among the multiple incoming sections 3, having the shortest transport time from the compartment 11.

In the example shown in FIG. 9, the first target article Wt1 stored in the compartment 11 having a shorter transport time from the first incoming section 3A than from the second incoming section 3B is transported to the first incoming section 3A, and the second target article Wt2 stored in the compartment 11 having a shorter transport time from the second incoming section 3B than from the first incoming section 3A is transported to the second incoming section 3B. In the second transport process to be performed later, when the target article Wt is not returned to the compartment 11 that has originally stored the target article Wt (the compartment 11 that is a transport source of the target article Wt in the first transport process), or specifically, when the storage destination compartment 11i and the restorage destination compartment 11r are different, the target article Wt may be transported to the incoming section 3, among the incoming sections 3, having the shortest transport time from the restorage destination compartment 11r.

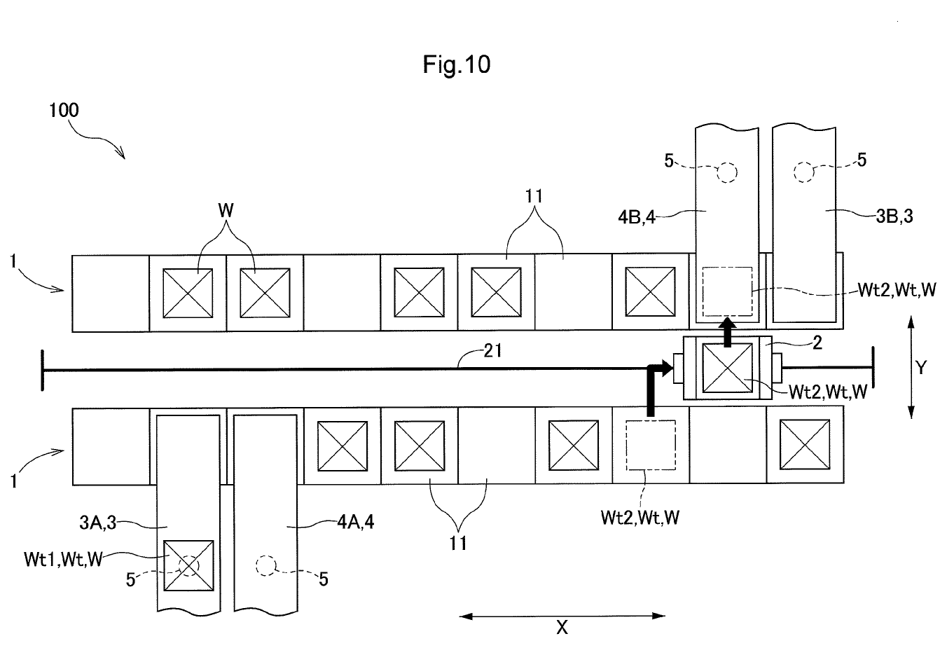

As shown in FIG. 10, the target articles Wt may be transported to one of the outgoing sections 4 in addition to the incoming section 3 in the first transport process. More specifically, when performing the regeneration process for each target article Wt, the control system 10 may perform the first transport process for each target article Wt to cause the transporter 2 to distribute the target articles Wt to the incoming section 3 and the outgoing section 4, and may perform the second information obtaining process for each target article Wt to cause the identification information obtainer 5 in the incoming section 3 and the identification information obtainer 5 in the outgoing section 4 to obtain the identification information of the target articles Wt.

In the example shown in FIG. 10, the control system 10 causes the transporter 2 to transport the second target article Wt2 to the second outgoing section 4B in the first transport process in a period overlapping the period in which the identification information obtainer 5 disposed in the first incoming section 3A obtains the identification information of the first target article Wt1 in the second information obtaining process.

### Other Embodiments

(1) In the above embodiment, articles W are FOUPs or FOSBs. In some embodiments, articles W may be pallets on which multiple products are loaded or may be products.

(2) In the above embodiment, the incoming sections 3 and the outgoing sections 4 are conveyors. In some embodiments, for example, at least one of the incoming section 3 or the outgoing section 4 may be a port that transfers articles W without transporting them.

(3) In the above embodiment, the transporter 2 is a stacker crane. In some embodiments, for example, the transporter 2 may be a transport vehicle or a conveyor.

(4) In the above embodiment, each identification information obtainer 5 includes the reader that reads the identifiers held by the identifier holders attached to articles W and the shape detector that detects the shapes of articles W. In some embodiments, for example, the identification information obtainer 5 may eliminate the shape detector. In this structure, the identification information of each article W may or may not include the type of article W determined based on the shape of the article W.

(5) In the above embodiment, the structure includes two incoming sections 3 (the first incoming section 3A and the second incoming section 3B) and two outgoing sections 4 (the first outgoing section 4A and the second outgoing section 4B). In some embodiments, the structure may include one or three or more incoming sections 3 or one or three or more outgoing sections 4.

(6) In the above embodiment, the control system 10 performing the regeneration process for each target article Wt causes the transporter 2 to transport the second target article Wt2 to the second incoming section 3B in the first transport process in a period overlapping the period in which the identification information obtainer 5 disposed in the first incoming section 3A obtains the identification information of the first target article Wt1 in the second information obtaining process. In some embodiments, the regeneration process for the second target article Wt2 may be started after the regeneration process for the first target article Wt1 is complete.

(7) The structure described in each of the above embodiments may be combined with the structures described in other embodiments unless any contradiction arises. The embodiments described herein are mere examples in all respects. Thus, the embodiments described herein may be modified variously as appropriate without departing from the spirit and scope of the disclosure.

### Overview of Present Embodiment

The overview of the automated warehouse described above will be described below.

An automated warehouse includes a storage rack including a plurality of compartments that each store an article, at least one incoming section in which articles are received into the automated warehouse, a transporter that transports articles between the at least one incoming section and a compartment among the plurality of compartments, a control system, and at least one identification information obtainer disposed in the at least one incoming section to obtain identification information of articles. The control system performs a first information obtaining process to cause the at least one identification information obtainer to obtain the identification information of an incoming article that is an article moved to the at least one incoming section to be received into the automated warehouse, and a first incoming process to cause the transporter to transport the incoming article to a storage destination compartment after the first information obtaining process. The storage destination compartment is a compartment among the plurality of compartments. The control system performs a first generation process to generate article management information including information indicating a position of the storage destination compartment in a manner associated with the identification information obtained in the first information obtaining process, and a regeneration process to perform regeneration of the article management information in response to an event that causes the regeneration to be performed. The regeneration process includes a first transport process for causing the transporter to transport at least one target article to the at least one incoming section from a compartment among the plurality of compartments. The at least one target article is at least one article corresponding to the article management information to be regenerated. The regeneration process includes a second information obtaining process for causing the at least one identification information obtainer to obtain the identification information of the at least one target article after the first transport process, and a second transport process for causing the transporter to transport the at least one target article to a restorage destination compartment after the second information obtaining process. The restorage destination compartment is a compartment among the plurality of compartments. The regeneration process includes a second generation process for regenerating the article management information including information indicating a position of the restorage destination compartment in a manner associated with the identification information obtained in the second information obtaining process.

In this structure, the identification information obtainer disposed in the incoming section obtains both the identification information of the incoming article in the first information obtaining process and the identification information of the target article in the second information obtaining process. This allows the identification obtaining device installed in the incoming section to be shared by both the first information obtaining process and the second information obtaining process without an identification obtaining device being separately installed in any of the compartments in addition to the incoming section. This can avoid decreasing the number of articles storable in the storage rack due to installation of the identification information obtainer.

The above structure also reduces the number of identification information obtainers being installed, as compared with the structure in which the identification information obtainer is installed separately in any of the compartments in addition to the incoming section.

In the above automated warehouse, the at least one incoming section may include a plurality of incoming sections. The at least one identification information obtainer may include a plurality of identification information obtainers each disposed in a corresponding incoming section of the plurality of incoming sections. The at least one target article may include a plurality of target articles. In the regeneration process for each of the plurality of target articles, the control system may perform the first transport process for each of the plurality of target articles to cause the transporter to distribute the plurality of target articles to the plurality of incoming sections, and perform the second information obtaining process for each of the plurality of target articles to cause the plurality of identification information obtainers to obtain the identification information of the plurality of respective target articles.

In this structure, the target articles are distributed to multiple incoming sections in the regeneration process for each target article. The identification information obtainers disposed in the respective incoming sections obtain the identification information of the target articles in a cooperative manner. This easily shortens the time taken for performing the regeneration process for all target articles.

In the above automated warehouse, the at least one incoming section may include a plurality of incoming sections. The at least one identification information obtainer may include a plurality of identification information obtainers each disposed in a corresponding incoming section of the plurality of incoming sections. The control system may cause, in the first transport process, the transporter to transport the at least one target article to an incoming section, among the plurality of incoming sections, having a shortest transport time from the compartment.

This structure can efficiently perform the first transport process. This easily shortens the time taken for performing the regeneration process for all target articles.

In the above automated warehouse, the at least one incoming section may include a plurality of incoming sections including a first incoming section and a second incoming section different from the first incoming section. The at least one identification information obtainer may include a plurality of identification information obtainers each disposed in a corresponding incoming section of the plurality of incoming sections. The at least one target article may include a plurality of target articles including a first target article and a second target article different from the first target article. In the regeneration process for each of the plurality of target articles, the control system may cause the identification information obtainer disposed in the first incoming section to obtain, in the second information obtaining process, the identification information of the first target article in a first period, and cause the transporter to transport, in the first transport process, the second target article to the second incoming section in a second period overlapping the first period.

This structure can perform the first transport process for the second target article in the period in which the second information obtaining process is performed for the first target article. This easily shortens the time taken for performing the regeneration process for all target articles.

The above automated warehouse may further include an outgoing section in which articles are transported out of the automated warehouse. The at least one identification information obtainer may include an identification information obtainer disposed in the outgoing section. The at least one target article may include a plurality of target articles. In the regeneration process for each of the plurality of target articles, the control system may perform the first transport process for each of the plurality of target articles to cause the transporter to distribute the plurality of target articles to the at least one incoming section and the outgoing section, and perform the second information obtaining process for each of the plurality of target articles to cause the at least one identification information obtainer in the at least one incoming section and the identification information obtainer in the outgoing section to obtain the identification information of a corresponding target article of the plurality of target articles.

In this structure, the target articles are distributed to the incoming section and the outgoing section in the regeneration process for each target article. The identification information obtainer disposed in the incoming section and the identification information obtainer disposed in the outgoing section obtain the identification information of the multiple target articles in a cooperative manner. This easily shortens the time taken for performing the regeneration process for all target articles.

The above automated warehouse may further include an outgoing section in which articles are transported out of the automated warehouse. The at least one target article may include a plurality of target articles. In the regeneration process for each of the plurality of target articles, the control system may cause the transporter to transport an outgoing article that is one of the plurality of target articles to the outgoing section with priority over performing the regeneration process for target articles other than the outgoing article in response to the outgoing article being determined to be transported out of the automated warehouse before the regeneration process is complete for all the plurality of target articles and in response to the identification information of the outgoing article being obtained in the second information obtaining process.

This structure can promptly transport intended articles out of the automated warehouse during the regeneration process for each target article.

### INDUSTRIAL APPLICABILITY

The technique according to one or more embodiments of the present disclosure can be used in an automated warehouse including a storage rack with multiple compartments that can each store an article, an incoming section in which articles are received into the automated warehouse, a transporter that transports articles between the incoming section and any of the compartments, and a control system.

What is claimed is:

1. An automated warehouse, comprising:
a storage rack comprising a plurality of compartments each configured to store an article;
at least one incoming section in which articles are received into the automated warehouse;
a transporter configured to transport articles between the at least one incoming section and a compartment among the plurality of compartments;
a control system; and
at least one identification information obtainer disposed in the at least one incoming section and configured to obtain identification information of articles, and
wherein the control system is configured to perform:
a first information obtaining process to cause the at least one identification information obtainer to obtain the identification information of an incoming article that is an article moved to the at least one incoming section to be received into the automated warehouse,
a first incoming process to cause the transporter to transport the incoming article to a storage destination compartment after the first information obtaining process, the storage destination compartment being a compartment among the plurality of compartments,
a first generation process to generate article management information including information indicating a position of the storage destination compartment in a manner associated with the identification information obtained in the first information obtaining process, and
a regeneration process to perform regeneration of the article management information in response to an event that causes the regeneration to be performed and,
the regeneration process comprising:
a first transport process for causing the transporter to transport at least one target article to the at least one incoming section from a compartment among the plurality of compartments, the at least one target article being at least one article corresponding to the article management information to be regenerated,
a second information obtaining process for causing the at least one identification information obtainer to obtain the identification information of the at least one target article after the first transport process,
a second transport process for causing the transporter to transport the at least one target article to a restorage destination compartment after the second information obtaining process, the restorage destination compartment being a compartment among the plurality of compartments, and
a second generation process for regenerating the article management information including information indicating a position of the restorage destination compartment in a manner associated with the identification information obtained in the second information obtaining process.

2. The automated warehouse according to claim 1, wherein:
the at least one incoming section comprises a plurality of incoming sections,
the at least one identification information obtainer comprises a plurality of identification information obtainers each disposed in a corresponding incoming section of the plurality of incoming sections,
the at least one target article comprises a plurality of target articles, and
in the regeneration process for each of the plurality of target articles, the control system performs the first transport process for each of the plurality of target articles to cause the transporter to distribute the plurality of target articles to the plurality of incoming sections, and performs the second information obtaining process for each of the plurality of target articles to cause the plurality of identification information obtainers to obtain the identification information of the plurality of respective target articles.

3. The automated warehouse according to claim 1, wherein:
the at least one incoming section comprises a plurality of incoming sections,
the at least one identification information obtainer comprises a plurality of identification information obtainers each disposed in a corresponding incoming section of the plurality of incoming sections, and
the control system causes, in the first transport process, the transporter to transport the at least one target article to an incoming section, among the plurality of incoming sections, having a shortest transport time from the compartment.

4. The automated warehouse according to claim 1, wherein:
the at least one incoming section comprises a plurality of incoming sections comprising a first incoming section and a second incoming section different from the first incoming section,
the at least one identification information obtainer comprises a plurality of identification information obtainers each disposed in a corresponding incoming section of the plurality of incoming sections,
the at least one target article comprises a plurality of target articles comprising a first target article and a second target article different from the first target article, and
in the regeneration process for each of the plurality of target articles, the control system causes the identification information obtainer disposed in the first incoming section to obtain, in the second information obtaining process, the identification information of the first target article in a first period, and causes the transporter to transport, in the first transport process, the second target article to the second incoming section in a second period overlapping the first period.

5. The automated warehouse according to claim 1, further comprising:
an outgoing section in which articles are transported out of the automated warehouse,
wherein the at least one identification information obtainer comprises an identification information obtainer disposed in the outgoing section,
wherein the at least one target article comprises a plurality of target articles, and
wherein in the regeneration process for each of the plurality of target articles, the control system performs the first transport process for each of the plurality of target articles to cause the transporter to distribute the plurality of target articles to the at least one incoming section and the outgoing section, and performs the second information obtaining process for each of the plurality of target articles to cause the at least one identification information obtainer in the at least one incoming section and the identification information obtainer in the outgoing section to obtain the identification information of a corresponding target article of the plurality of target articles.

6. The automated warehouse according to claim 1, further comprising:
an outgoing section in which articles are transported out of the automated warehouse,
wherein the at least one target article comprises a plurality of target articles, and
wherein in the regeneration process for each of the plurality of target articles, the control system causes the transporter to transport an outgoing article that is one of the plurality of target articles to the outgoing section with priority over performing the regeneration process for target articles other than the outgoing article in response to the outgoing article being determined to be transported out of the automated warehouse before the regeneration process is complete for all the plurality of target articles and in response to the identification information of the outgoing article being obtained in the second information obtaining process.
